(19) United States
(12) Patent Application Publication
(10) Pub. No.: US 2014/0253424 A1
(43) Pub. Date: Sep. 11, 2014

(54) SHIFT REGISTER, BIDIRECTIONAL SHIFT REGISTER APPARATUS, AND LIQUID CRYSTAL DISPLAY PANEL USING THE SAME

(71) Applicant: Hannstar Display Corporation, New Taipei City (TW)

(72) Inventors: Chia-Hua Yu, New Taipei City (TW); Sung-Chun Lin, Tainan City (TW); Hsuan-Chen Liu, Kaohsiung City (TW); Chien-Ting Chan, Tainan City (TW)

(21) Appl. No.: 13/941,547

(22) Filed: Jul. 15, 2013

(30) Foreign Application Priority Data
Mar. 11, 2013 (CN) 201310076420.3

(51) Int. Cl. G11C 19/28; G09G 3/36

(52) U.S. Cl. CPC G11C 19/28; G09G 3/3674
USPC 345/100; 377/64; 377/69

(57) ABSTRACT

A shift register, a bidirectional shift register apparatus and a liquid crystal display panel using the same are provided. The shift register includes a precharge unit, a pull up unit, and a pull down unit. The precharge unit receives outputs of a previous two-stage of shift register and a next two-stage of shift register both corresponding to the shift register to thereby generate a precharge signal. The pull up unit is coupled to the precharge unit, and receives the precharge signal and a first input clock signal to thereby output a scan signal. The pull down unit is coupled to the precharge unit and the pull up unit, and receives the precharge signal, the first input clock signal and a second input clock signal to control a voltage level of the scan signal, where the first input clock signal and the second input clock signal are inverted in phase.

### CROSS-REFERENCE TO RELATED APPLICATION

This application claims the priority benefit of China application serial no. 201310076420.3, filed on Mar. 11, 2013. The entirety of the above-mentioned patent application is hereby incorporated by reference herein and made a part of this specification.

### BACKGROUND OF THE INVENTION

1. Field of the Invention

The present invention relates to a flat display technology, and more particularly, to a shift register, a bidirectional shift register apparatus, and a liquid crystal display panel using the same.

2. Description of Related Art

In recent years, following the vigorous development of semiconductor technology, portable electronic products and flat display products are being widely used. Along various types of flat displays, liquid crystal displays (LCDs) have become the main stream due to the advantages of low voltage operation, zero radiation, light weight and small size. Also because of this, manufactures have been driven to develop more miniaturized liquid crystal displays with lower cost.

In order to reduce the manufacturing cost of the liquid crystal displays, some manufactures have developed a technique that, when the liquid crystal display panel employs an amorphous silicon (a-Si) process, the shift registers inside the scan driver IC that was originally disposed at a scan side of the liquid display panel are transferred to be directly disposed on a glass substrate of the liquid crystal display panel. Therefore, the scan driver IC that was originally disposed at the scan side of the liquid display panel can be omitted, thereby reducing the manufacturing cost of the liquid crystal displays.

### SUMMARY OF THE INVENTION

Accordingly, the present invention is directed to a shift register, a bidirectional shift register apparatus and a liquid crystal display panel using the same, which can use less control signals to achieve two-way scan driving scheme and have an improved reliability.

The present invention provides a shift register which includes a precharge unit, a pull up unit and a pull down unit. The precharge unit receives outputs of a previous two-stage of shift register and a next two-stage of shift register both corresponding to the shift register to thereby generate a precharge signal. The pull up unit is coupled to the precharge unit, and receives the precharge signal and a first input clock signal to thereby output a scan signal. The pull down unit is coupled to the precharge unit and the pull up unit, and receives the precharge signal, the first input clock signal and a second input clock signal to control a voltage level of the scan signal. The first input clock signal and the second input clock signal are inverted in phase (or reverse to each other).

The present invention further provides a bidirectional shift register apparatus adapted for a liquid crystal display panel, which includes N shift registers, as the above provided shift register, connected in series with each other and disposed on a left side of a display area of the liquid crystal display panel.

The present invention further provides a bidirectional shift register apparatus adapted for a liquid crystal display panel, which includes M shift registers, as the above provided shift register, connected in series with each other and disposed on a right side of a display area of the liquid crystal display panel.

The present invention further provides a liquid crystal display panel which includes a display area and two bidirectional shift register apparatuses described above. The two bidirectional shift register apparatuses are disposed on left and right sides of the display area, respectively.

In view of the foregoing, embodiments of the present invention provide a shift register, a bidirectional shift register apparatus and a liquid crystal display panel using the same. The shift register can employ the circuit architecture of the dynamic inverter for node discharging, thereby controlling the voltage level of the outputted scan signals and hence effectively increasing the overall reliability of the bidirectional shift register apparatus. In addition, based on the architecture of the bidirectional shift register apparatus of the embodiment of the present invention, the bidirectional shift register apparatus can use less control signals to achieve forward and backward scan driving scheme, thereby reducing the circuit layout area of the liquid crystal display panel using the bidirectional shift register apparatus.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

FIG. 1 illustrates a liquid crystal display according to one embodiment of the present invention.

FIG. 2A and FIG. 2B illustrate the bidirectional shift register apparatuses according to the embodiment of FIG. 1.

FIG. 3A illustrates the shift register according to the embodiment of FIG. 2A.

FIGS. 3B to 3E illustrate circuit operations of the first to fourth shift registers according to the embodiment of FIG. 3A.

FIG. 4 illustrates a circuit diagram of the shift register according to the embodiment of FIG. 3A.

FIGS. 5A and 5B illustrate a signal sequence of the bidirectional shift register apparatus according to one embodiment of the present invention.

FIGS. 6A and 6B illustrate a signal sequence of the bidirectional shift register apparatus according to another embodiment of the present invention.

### DESCRIPTION OF THE EMBODIMENTS

Embodiments of the present invention provide a shift register, a bidirectional shift register apparatus and a liquid crystal display panel using the same. The shift register can employ the circuit architecture of a dynamic inverter for node discharging, thereby controlling the voltage level of outputted scan signals and hence effectively increasing the overall reliability of the bidirectional shift register apparatus. In addition, based on the architecture of the bidirectional shift register apparatus of the embodiments of the present invention, the bidirectional shift register apparatus can use less control signals to achieve forward and backward scan driving scheme, thereby reducing the circuit layout area of the liquid crystal display panel using the bidirectional shift register apparatus. In the following detailed description of the preferred embodiments, reference is made to the accompanying drawings which form a part hereof, and in which are shown by way of illustration specific embodiments in which the invention may be practiced. In addition, where possible, the same reference numerals are used to denote the same or similar elements/parts/steps throughout the specification.

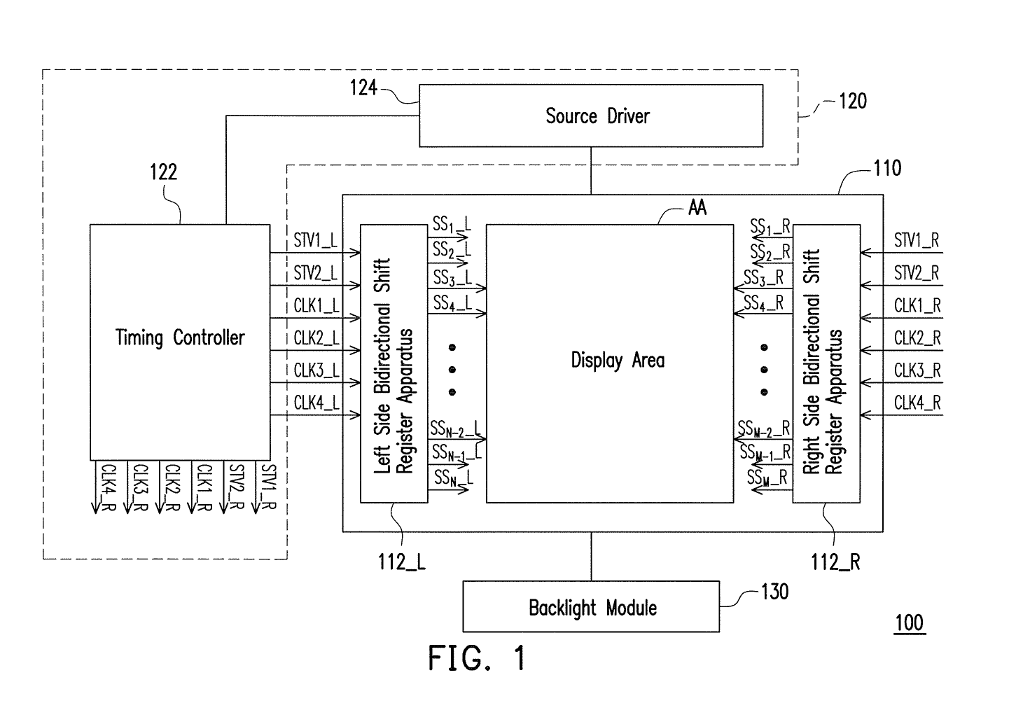

FIG. 1 illustrates a liquid crystal display according to one embodiment of the present invention. Referring to FIG. 1, the liquid crystal display 100 includes a liquid display panel 110, a driving circuit 120, and a backlight module 130 for providing a (back-) light source for the liquid crystal panel 110.

The liquid crystal display 110 includes a substrate (not shown, for example, a glass substrate), a plurality of pixels (not shown), and bidirectional shift register apparatuses 112_L and 112_R. In the liquid crystal display panel 110, the pixels are disposed on the substrate and arranged in an array within a display area AA. The bidirectional shift register apparatuses 112_L and 112_R are directly disposed on opposite sides of the display area AA, and are coupled to odd number row pixels and even number row pixels through corresponding scan lines, respectively.

The driving circuit 120 includes a timing controller (T-con) 122 and a source driver 124. In the driving circuit 120, the timing controller 120 can provide multiple preset clock signals (e.g. STV1_L, STV2_L, STV1_R, STV2_R, CLK1_L to CLK4_L, CLK1_R to CLK4-R) to control operations of the source driver 124 and the bidirectional shift register apparatuses 112_L and 112_R. The source driver 124 outputs multiple pixel voltages to drive the liquid crystal display panel 110 to display image(s) under the control of the timing controller 122.

Specifically, the left side bidirectional shift register apparatus 112_L outputs multiple scan signals SS₁_{_{—}}L to SS_{N}_{_{—}}L in response to the start pulse signals STV1_L and STV2_L and clock signals CLK1_L to CLK4_L provided by the timing controller 122, where the scan signals SS_{N}_{_{—}}L, SS1_L, SS_{N-1}_{_{—}}L and SS_{N}-L are dummy scan signals (which are not provided to the liquid crystal display panel 110 but only serve as a basis for generating other scan signals), and the scan signals SS₃_{_{—}}L to SS_{N-2}_{_{—}}L are provided to the odd number row pixels through the corresponding scan lines to thereby sequentially turn on the odd number row pixels. Here, N is the row number of the corresponding odd number row pixels which is a preset positive integer (in the present embodiment, N equals to the row number of the odd number row pixels plus four).

Similarly, the right side bidirectional shift register apparatus 112_R outputs multiple scan signals SS₁_{_{—}}R to SS_{M}_{_{—}}R in response to the start pulse signals STV1_R and STV2_R and clock signals CLK1_R to CLK4_R, where the scan signals SS₁_{_{—}}R, SS₂_{_{—}}R, SS_{M-1}_{_{—}}R and SS_{M}_{_{—}}R are dummy signals, and the scan signals SS₃_{_{—}}R to SS_{M-2}_{_{—}}R are provided to the even number row pixels through the corresponding scan lines to thereby sequentially turn on the even number row pixels. Here, M is the row number of the corresponding odd number row pixels which is a preset positive integer (in the present embodiment, M equals to the row number of the even number row pixels plus four).

According to the above driving manner, each row of pixels of the liquid crystal display panel 110 is sequentially turned on according to the corresponding scan signals SS₃_{_{—}}L to SS_{N-2}_{_{—}}L and SS₃_{_{—}}R to SS_{M-2}_{_{—}}R, thereby enabling the liquid crystal display panel 110 to display the image(s). In the present embodiment, the timing controller 122 can control the scan sequence of the bidirectional shift register apparatuses 112_L and 112_R by providing different preset clock signals, such that the bidirectional shift register apparatuses 112_L and 112_R sequentially turn on each row of pixels in a forward (for the first row to the last row) or backward (from the last row to the first row) scan sequence.

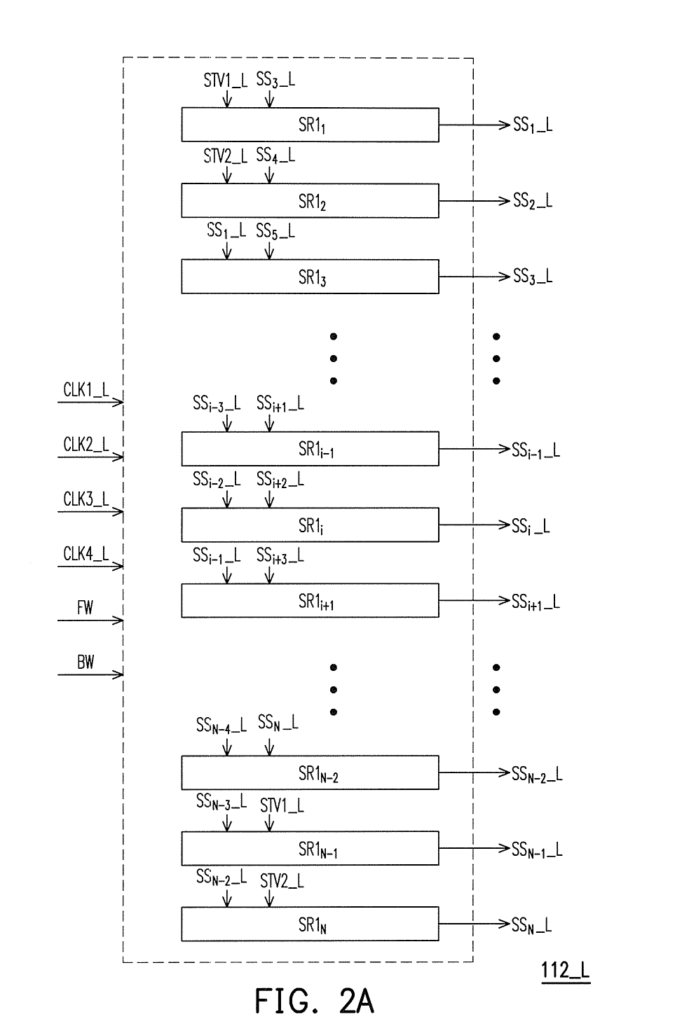

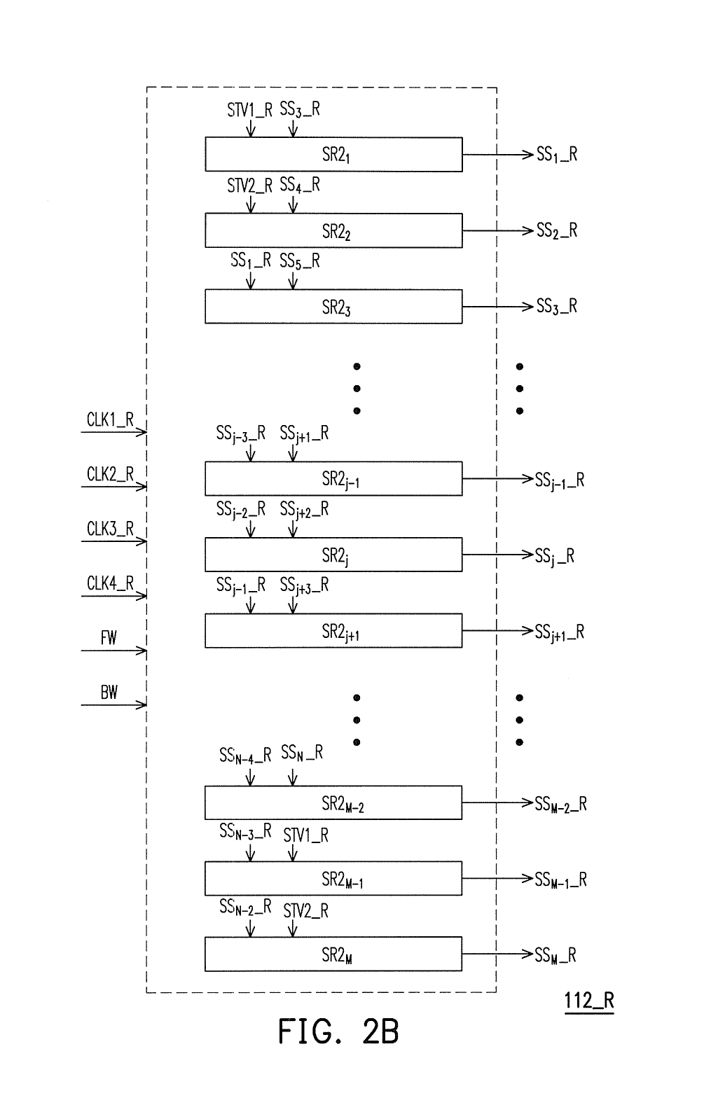

More specifically, FIG. 2A and FIG. 2B illustrate the bidirectional shift register apparatuses 112_L and 112_R, respectively. Referring first to FIG. 2A, the left side bidirectional shift register apparatus 112_L includes N shift registers SR1₁ to SR1_{N} that are substantially the same and connected in series with each other, where the first, second, (N−1)-th and N-th shift registers SR1₁, SR1₂, SR1_{N-1}, SR1_{N} are all dummy shift registers that output dummy scan signals, and the third shift registers SR1₃ to the (N−2)-th shift register SR1_{N-2} are coupled to the odd number row pixels through the corresponding scan lines. Similarly, referring to FIG. 2B, the right side bidirectional shift register apparatus 112_R includes M shift registers SR2₁ to SR2_{M} that are substantially the same and connected in series with each other, where the first, second, (M−1)-th and M-th shift registers SR2₁, SR2₂, SR2_{M-1}, SR2_{M} are all dummy shift registers that output dummy scan signals, and the third shift registers SR2₃ to the (M−2)-th shift register SR1_{M-2} are coupled to the even number row pixels through the corresponding scan lines.

In the present embodiment, the bidirectional shift register apparatuses 112_L and 112_R can sequentially output scan signals SS₁_{_{—}}L to SS_{N}_{_{—}}L and SS₁_{_{—}}R to SS_{M}_{_{—}}R in the forward or backward scan sequence according to a forward input signal FW and a backward input signal BW, where the forward input signal FW and the backward input signal BW can be two of the preset clock signals provided by the timing controller 122, or can be provided by another signal generating unit. Therefore, generation of the forward and backward input signals are not intended to be limited to any particular manner. Moreover, each of the forward input signal FW and the backward input signal BW also can be a DC voltage level, for example, high voltage level or low voltage level.

In the embodiment below, each of the shift registers SR1₁ to SR1_{N} and SR2₁ to SR2_{M} has the same operation principle and circuit architecture and, therefore, the description below is made mainly in connection with the i-th shift register SR1ᵢ of the bidirectional shift register apparatus 112_L as an example. People skilled in the art can directly and unambiguously deduce the operation principle and circuit architecture of the right side bidirectional shift register apparatus 112_R and each shift register SR2₁ to SR2_{M} thereof from the below description. Therefore, in later embodiments, the description is made only with respect to the difference between right side two-way temporary storage device 112_R and the left side bidirectional shift register apparatus 112_L, and contents that are the same are not repeated herein.

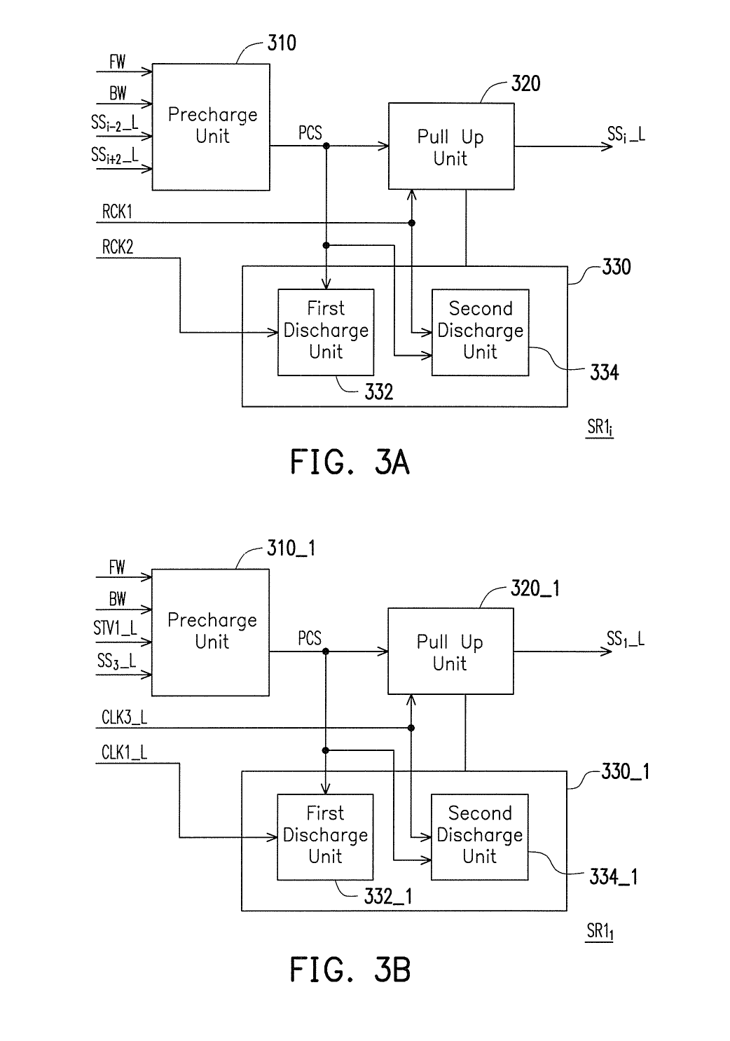

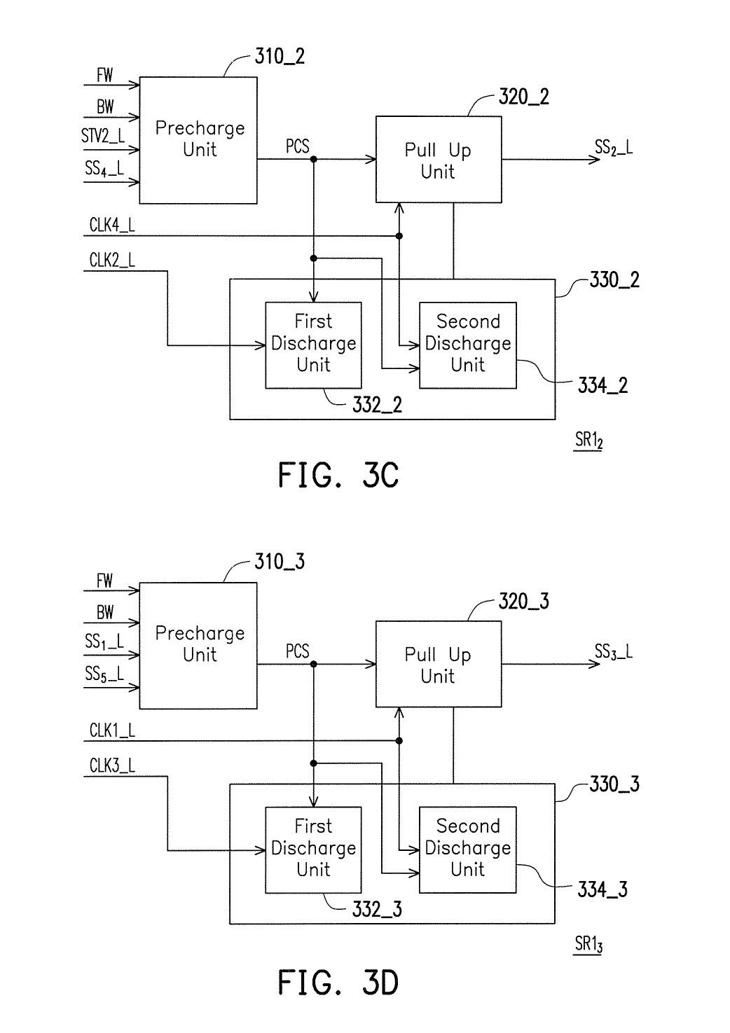

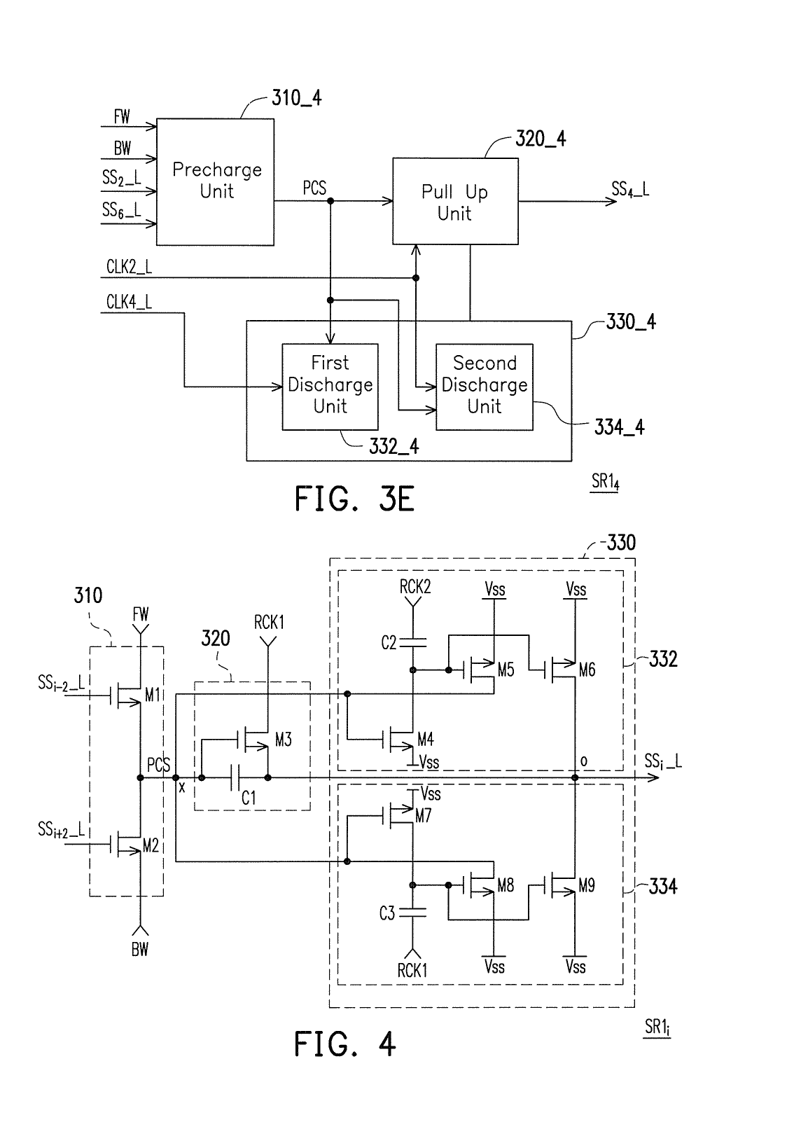

FIG. 3A illustrates the shift register of FIG. 2A. Referring to FIG. 2A and FIG. 3A, the i-th shift register SR1ᵢ includes a precharge unit 310, a pull up unit 320, and a pull down unit 330. The precharge unit 310 receives outputs of the (i−2)-th and (i+2)-th shift registers SR1ᵢ₋₂ and SR1ᵢ₊₂, and accordingly outputs a precharge signal PCS, where 3≦i≦N−2. In other words, the precharge unit 310 of each shift register SR1ᵢ except for the dummy shift registers receives the scan signals SSᵢ₋₂_{_{—}}L and SSᵢ₊₂_{_{—}}L outputted by the previous two-stage of shift register SR1ᵢ₋₂ and the next two-stage of shift register SR1ᵢ₊₂ both corresponding to the i-th shift register SR1ᵢ to thereby generate the corresponding precharge signal PCS.

The dummy shift registers use the start pulse signals STV1_L and STV2_L provided by the timing controller 122 to generate corresponding precharge signals PCS, respectively. For example, the precharge unit of the first shift register SR1ᵢ receives the start pulse signal STV_L and the scan signal SS₃_{_{—}}L outputted by the third shift register SR1₃, the precharge unit of the second shift register SR1₂ receives the start pulse signal STV2_L and the scan signal SS₄_{_{—}}L outputted by the fourth shift register SR1₄, the precharge unit of the (N−1)-th shift register SR1_{N-}1 receives the scan signal SS_{N-3}_{_{—}}L outputted by the (N−3)-th shift register SR1_{N-3} and the start pulse signal STV1_L, and the precharge unit of the shift register SR1_{N} receives the scan signal SS_{N-2}_{_{—}}L outputted by the (N−2)-th shift register SR1_{N-2} and the start pulse signal STV2_L.

In addition, the precharge unit of each shift register SR1ᵢ to SR1_{N} further receives the forward input signal FW and the backward input signal BW, such that the left side bidirectional shift register apparatus 112_L drives the odd number row pixels in the forward or backward scan sequence according to the forward input signal FW and the backward input signal BW. For example, the left side bidirectional shift register apparatus 112_L can drive the odd number row pixels in the sequence from the first row to the last row (forward sequence) according to an enabled forward input signal FW and a disabled backward input signal BW, and can drive the odd number row pixels in the sequence from the last row to the first row (backward sequence) according to a disabled forward input signal FW and an enabled backward input signal BW.

The pull up unit 320 is coupled to the precharge unit 310 to receive the precharge signal PCS and a first input clock signal RCK1 and to thereby output the scan signal SSᵢ_{_{—}}L. The pull down unit 330 is coupled to the precharge unit 310 and the pull up unit 320 and includes a first discharge unit 332 and a second discharge unit 334. The first discharge unit 332 receives the precharge signal PCS and a second input clock signal RCK2 and thereby determines whether to pull the scan signal SSᵢ_{_{—}}L down to a reference voltage level Vss (for example, but not limited to, a negative voltage). The second discharge unit 334 receives the precharge signal PCS and the first input clock signal RCK1 and thereby determines whether to maintain the scan signal SSᵢ_{_{—}}L at the reference voltage level Vss.

Specifically, the timing controller 122 sequentially provides different clock signals CLK1_L to CLK4_L to each shift registers SR1₁ to SR1_{N} as corresponding first input clock signal RCK1 and second input clock signal RCK2, such that each shift register SR1₁ to SR1_{N} can drive the odd number row pixels of the display area AA in the forward or backward scan sequence. The waveforms of the start pulse signals STV1_L and STV2_L and clock signals CLK1_L to CLK4_L provided by the timing controller 122 may be varied according to the forward or backward scan driving manner (which can be clearly seen from the signal sequence diagrams illustrated later).

As shown in FIGS. 3B to 3E, description is made in connection with the first to fourth shift registers SR1₁ to SR1₄ as an example under the forward scan driving state. Referring to FIG. 3B, the precharge unit 310_1 of the shift register SR1₁ receives the start pulse signal STV1_L and the scan signal SS₃_{_{—}}L, the pull up unit 320_1 and second discharge unit 334_1 of the shift register SR1₁ receive the clock signal CLK3_L as the first input clock signal RCK1, and the first discharge unit 332_1 of the shift register SR11 receives the clock signal CLK1_L as the second clock signal RCK2.

Referring to FIG. 3C, the precharge unit 3102 of the shift register SR1₂ receives the start pulse signal STV2_L and scan signal SS₄_{_{—}}L, the pull up unit 3202 and the second discharge unit 334_2 of the shift register SR12 receive the clock signal CLK4_L as the first input clock signal RCK1, and the first discharge unit 332_2 of the shift register SR12 receives the clock signal CLK2_L as the second clock signal RCK2.

Referring to FIG. 3D, the precharge unit 310_3 of the shift register SR1₃ receives the scan signals SS₁_{_{—}}L and SS₅_{_{—}}L, the pull up unit 320_3 and the second discharge unit 334_3 of the shift register SR1₃ receive the clock signal CLK1_L as the first input clock signal RCK1, and the first discharge unit 332_3 of the shift register SR13 receives the clock signal CLK3_L as the second clock signal RCK2.

Referring to FIG. 3E, the precharge unit 310_4 of the shift register SR1₄ receives the scan signals SS₂_{_{—}}L and SS₆_{_{—}}L, the pull up unit 320_4 and the second discharge unit 334_4 of the shift register SR1₄ receive the clock signal CLK2_L as the first input clock signal RCK1, and the first discharge unit 332_4 of the shift register SR14 receives the clock signal CLK4_L as the second clock signal RCK2.

Similar to the first shift register SR1₁, the fifth shift register SR1₅ receives the clock signal CLK3_L and CLK1_L as the first input clock signal RCK1 and the second input clock signal RCK2, and subsequent shift registers SR1₆ to SR1_{N} likewise receive the corresponding clock signals CLK1_L to CLK4_L as the first input clock signal RCK1 and the second input clock signal RCK2.

In other words, the (4k−3)-th shift register SRL (i=4k−3, k is an integer) receives the clock signals CLK3_L and CLK1_L as the first input clock signal RCK1 and the second input clock signal RCK2, respectively. The (4k−2)-th shift register SR1ᵢ (i=4k−2) receives the clock signals CLK4_L and CLK4_L as the first input clock signal RCK1 and the second input clock signal RCK2, respectively. The (4k−1)-th shift register SR1ᵢ (i=4k−1) receives the clock signals CLK1_L and CLK1_L as the first input clock signal RCK1 and the second input clock signal RCK2, respectively. The 4k-th shift register SR1ᵢ (i=4k) receives the clock signals CLK3_L and CLK1_L as the first input clock signal RCK1 and the second input clock signal RCK2, respectively. That is, each shift register SR1₁ to SR1_{N} sequentially receives the clock signals CLK3_L, CLK4_L, CLK1_L and CLK2_L as the first input clock signal RCK1, and sequentially receives the clock signals CLK1_L, CLK2_L, CLK3_L and CLK4_L as the second input signal RCK2.

For more clearly describing embodiments of the present invention, FIG. 4 illustrates a circuit diagram of the shift register according to the embodiment of FIG. 3A. Referring to FIG. 4, the precharge unit 310 includes transistors M1 and M2, the pull up unit 320 includes a transistor M3 and a capacitor C1, the first discharge unit 332 of the pull down unit 330 includes transistors M4 to M6 and a capacitor C2, and the second discharge unit 334 of the pull down unit 330 includes transistors M7 to M9 and a capacitor C3. Each transistor M1 to M9 is illustrated in the present embodiment as an N-type transistor. However, it is not intended to limit the transistors of the present invention to the N-type transistors.

In the precharge unit 310 of the i-th shift register SR1ᵢ, a gate of the transistor M1 receives the scan signal SSᵢ₋₂_{_{—}}L outputted by the (i−2)-th shift register SR1-2, and a drain of the transistor M1 receives the forward input signal FW. A gate of the transistor M2 receives the scan signal SSᵢ₊₂_{_{—}}L outputted by the (i+2)-th shift register SR1₁₊₂, a drain of the transistor M2 is coupled to a source of the transistor M1, and the drain of the transistor M2 and the source of the transistor M1 are commonly coupled to a node x to output the precharge signal PCS. A source of the transistor M2 receives the backward input signal BW.

In the pull up unit 310 of the i-th shift register SR1ᵢ, a gate of the transistor M3 receives the precharge signal. PCS via the node x, a drain of the transistor M3 receives the first input clock signal RCK1, and a source of the transistor M3 outputs the scan signal SSᵢ_{_{—}}L. A first terminal of the capacitor C1 is coupled to the gate of the transistor M3 and the node x, and a second terminal of the capacitor C1 is coupled to a source of the transistor M3.

In the first discharge unit 332 of the i-th shift register SR1ᵢ, a first terminal of the capacitor C2 receives the second input clock signal RCK2. A gate of the transistor M4 is coupled to the node x and receives the precharge signal PCS, a drain of the transistor M4 is coupled to a second terminal of the capacitor C2, and a source of the transistor M4 is coupled to the reference voltage level Vss. A gate of the transistor M5 is coupled to the second terminal of the capacitor C2 and the drain of the transistor M4, a drain of the transistor M5 is coupled to the gate of the transistor M4 and the node x, and a source of the transistor M5 is coupled to the reference voltage level Vss. A gate of the transistor M6 is coupled to the second terminal of the capacitor C2, the drain of the transistor M4 and the gate of the transistor M5. A drain of the transistor M6 is coupled to the source of the transistor M3 and the second terminal of the capacitor C1, and a source of the transistor M6 is coupled to the reference voltage level Vss.

In the second discharge unit 334 of the i-th shift register SR1ᵢ, a first terminal of the capacitor C3 receives a first input clock signal RCK1. A gate of the transistor M7 is coupled to the node x and receives the precharge signal PCS, a drain of the transistor M7 is coupled to a second terminal of the capacitor C3, and a source of the transistor M7 is coupled to the reference voltage level Vss. A gate of the transistor M8 is coupled to the second terminal of the capacitor C3 and a source of the transistor M7. A drain of the transistor M8 is coupled to the gate of the transistor M7 and the node x, and a source of the transistor M8 is coupled to the reference voltage level Vss. The gate of the transistor M9 is coupled to the second terminal of the capacitor C3, the source of the transistor M7 and the gate of the transistor M8. A drain of the transistor M9 is coupled to the sources of the transistors M3 and M6 and the second terminal of the capacitor C1, and a source of the transistor M9 is coupled to the reference voltage level Vss.

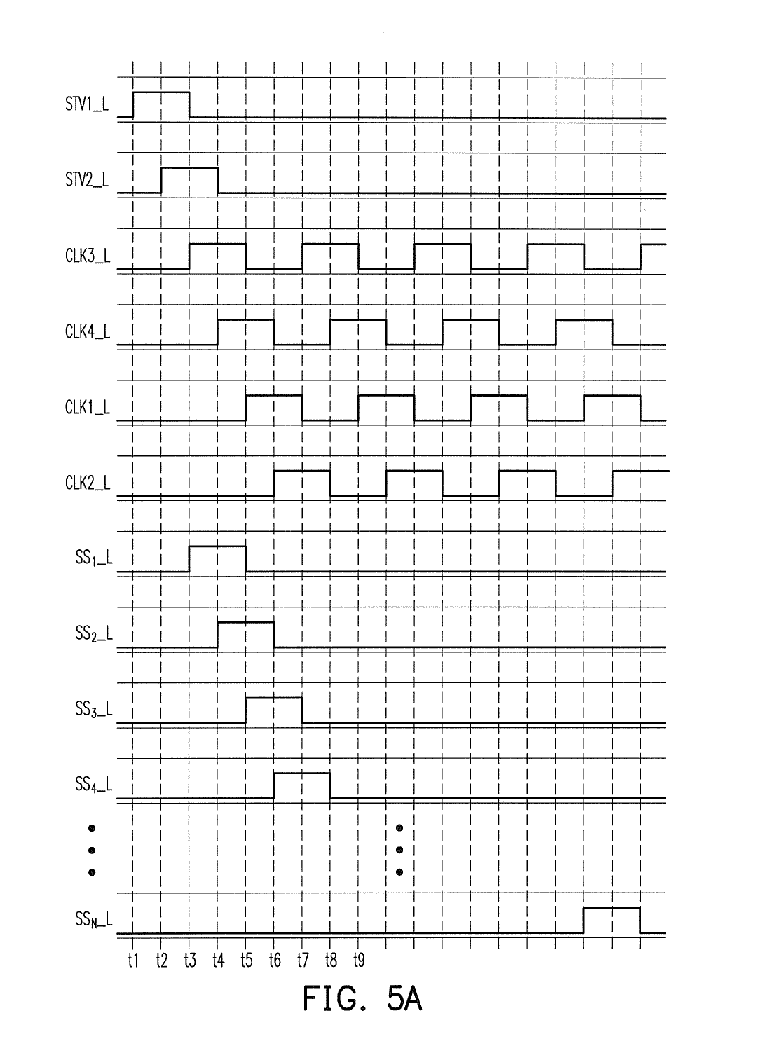

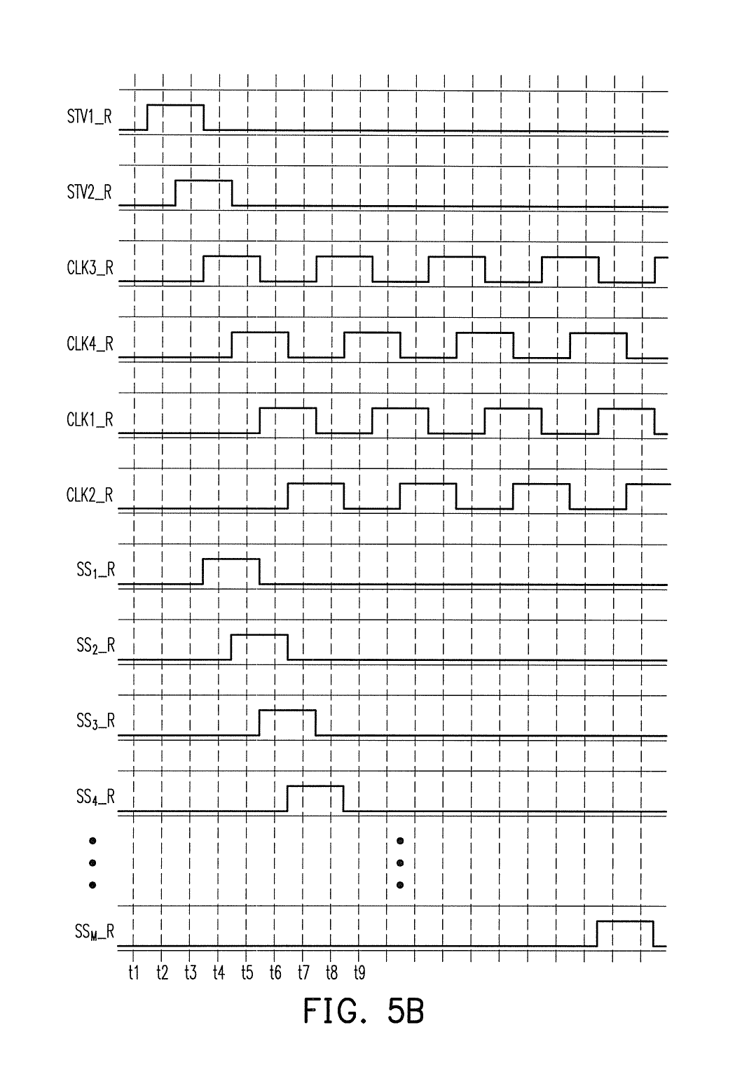

For clearly illustrating the operation principle of the shift register SR1ᵢ of FIG. 4, FIG. 5A illustrates the signal sequence of the left side bidirectional shift register apparatus 112_L performing a forward scan to the even number row pixels of the display area AA.

It can be clearly seen from FIG. 5A, under the forward scan driving state, the timing controller 122 provides clock signals CLK3_L, CLK4_L, CLK1_L and CLK2_L with specific duty cycles and different phase differences. In the present embodiment, the duty cycle of each clock signal CLK1_L to CLK4_L is illustrated to be 50% as an example, and the timing controller 122 generates the clock signals CLK1_L to CLK4_L in the order of CLK3_L→CLK4_L→CLK1_L→CLK2_L, with each being 90 degrees behind a previous clock signal. That is, the enabling time (the time for a signal increasing to a high voltage level, also referred to as a pulse width of each pulse) of each clock signal CLK3_L→CLK4_L→CLK1_L and CLK2_L is 50% overlapped with a previous clock signal. However, this is for the purposes of illustration only and should not be regarded as limiting. For example, the phase of the clock signal CLK4_L is behind the clock signal CLK3_L with a 90 degrees phase difference, the phase of the clock signal CLK1_L is behind the clock signal CLK4_L with a 90 degrees phase difference, and the phase of the clock signal CLK2_L is behind the clock signal CLK1_L with a 90 degrees phase difference.

In addition, in the present embodiment, the enabling time of a first pulse of the clock signal CLK3_L in a frame period is later than the enabling time of the start pulse signal STV2_L, and is 50% overlapped with the enabling time of the start pulse signal STV2_L. In addition, the phase of the start pulse signal STV2_L is behind the start pulse signal STV1_L, and the enabling time of the start pulse signal STV2_L is 50% overlapped with the enabling time of the start pulse signal STV1_L.

Referring to FIG. 2A, FIG. 4 and FIG. 5A, taking the first shift register SR1₁ as an example, during the period from time t1 to t3, the transistor M1 of the precharge unit 310 is turned on in response to the enabled start pulse signal STV1_L, and the transistor M2 is turned off in response to the disabled scan signal SS₃, such that the precharge unit 310 outputs the corresponding prcharge signal PCS to precharge the node x. During this period, because the pull up unit 320 receives the disabled clock signal CLK3_L, the scan signal SS₁_{_{—}}L is at the reference voltage level Vss no matter whether the transistor M3 is turned on by the precharge signal PCS.

During the period from time t3 to t5, the transistors M1 and M2 of the precharge unit 310 are turned off in response to the disabled start pulse signal STV1 and the disabled scan signal SS₃, respectively. The pull up unit 320 and the second discharge unit 334 receive the enabled clock signal CLK3_L, and the first discharge unit 332 receives the disabled clock signal CLK1_L. During this period, the node x is pulled up to a high voltage level due to a (capacitance) coupling effect between the drain and gate of the transistor M3, such that the transistor M3 is turned on to output high voltage level scan signal SS₁. On the other hand, the transistors M5 and M6 of the first discharge unit 332 are turned off in response to the disabled clock signal CLK1_L, and the transistor M7 of the second discharge unit 334 is turned on by the high voltage level of the node x thus making the transistor M8 and M9 turn off, such that the scan signal SS₁_{_{—}}L is pulled up from the reference voltage level Vss to the high voltage level at time t3 and is maintained at the high voltage level during the period from time t3 to t5.

In addition, under the condition that the clock signals CLK1_L and CLK3 have a phase difference which causes the enabling periods of the clock signal CLK1 and CLK3 to overlap, the transistor M4 of the first discharge unit 334 is turned on in response to the high voltage level of the node x and the enabled clock signal CLK1, such that the transistors M5 and M6 are maintained at the turn-off state. As such, the scan signal SS₁_{_{—}}L is less subject to the phase difference between the clock signals CLK1 and CLK3.

During the period from time t5 to t7, the transistor M1 of the precharge unit 310 is turned off in response to the disabled start pulse signal STV1_L, and the transistor M2 is turned on in response to the enabled scan signal SS₃. The pull up unit 320 and the second discharge unit 334 receive the disabled clock signal CLK3_L, and the first discharge unit 332 receives the enabled clock signal CLK1_L. During this period, the precharge unit 310 discharges the node x through the transistor M2 that has been turned on. In addition, the transistors M5 and M6 of the first discharge unit 332 are turned on in response to the enabled clock signal CLK1_L to discharge the node x and a node o, respectively. Therefore, the scan signal SS₁_{_{—}}L can be quickly pulled down to the reference voltage level Vss at time t5, and is maintained at the reference voltage level Vss during the period from time t5 to t7. In addition, the node x can be discharged during the period from time t5 to t7 through multiple discharge paths (transistors M2, M4, M5), which therefore reduces the probability of misoperation of the transistor M3 of the pull up unit 320.

During the period from time t7 to t9, the transistors M1 and M2 of the precharge unit 310 are turned off in response to the disabled start pulse signal STV1 and the disabled scan signal SS₃, respectively. The pull up unit 320 and the second discharge unit 334 receive the enabled clock signal CLK3_L, and the first discharge unit 332 receives the disabled clock signal CLK1_L. The node x was discharged to the reference voltage level Vss during the previous period and, therefore, the transistor M7 is not turned on during this period, such that the transistors M8 and M9 are turned on in response to the enabled clock signal CLK3_L, thereby continuously maintaining the node o at the reference voltage level Vss during the period from time t5 to t7.

For understanding of subsequent operations of the shift register SR1₁ during the same frame period, reference is made to the description above with respect to the operations during the periods from time t5 to t7 and t7 to t9, further explanation thereof is not repeated herein. In addition, operations of the other shift registers SR1₂ to SR1_{N} may be deduced from the above description and explanation thereof is therefore not repeated herein.

Specifically, in the above embodiment, the transistors M4 to M6 of the first discharge unit 332 and the transistors M7 to M9 of the second discharge unit 334 are similar to a dynamic inverter in function, which can discharge the node x and node o alternatively during different periods according to the corresponding input clock signals RCK1 and RCK2, respectively. As such, misoperation of the pull up unit 330 can be avoided.

In addition, under the architecture of FIG. 4, the first discharge unit 332 and the second discharge unit 334 can achieve the control of the shift registers SR1₁ to SR1_{N} by using only two signals (the precharge signal PCS and the first/second input clock signals RCK1/RCK2), which significantly reduces complexity of the control in comparison with the conventional shift register.

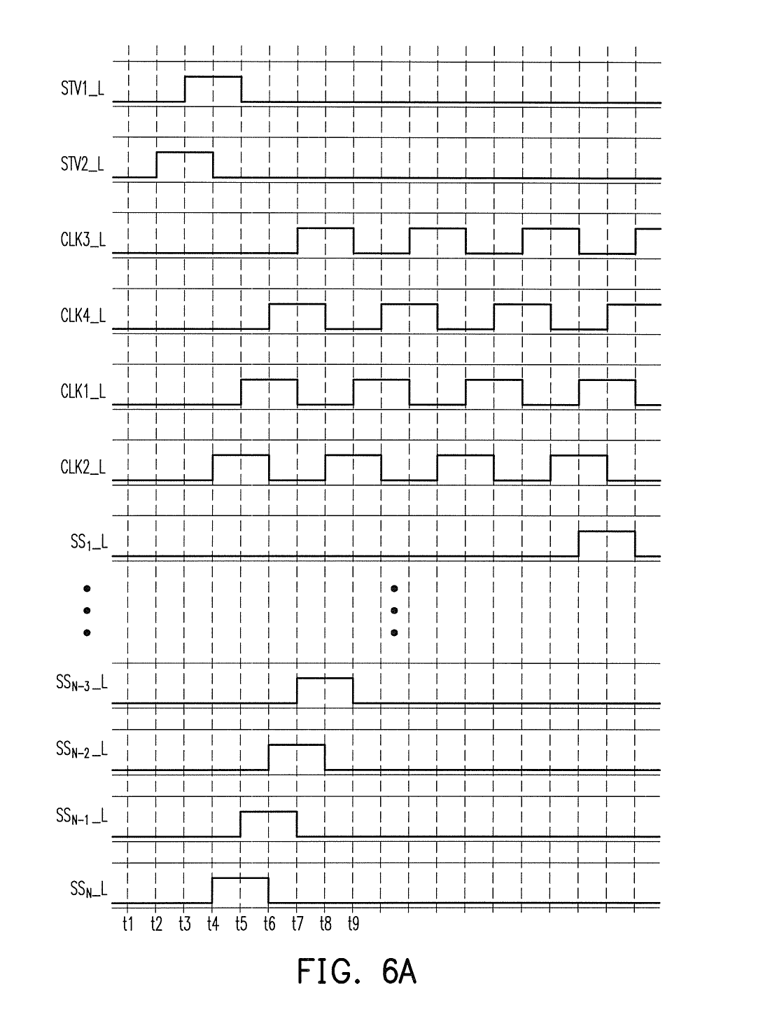

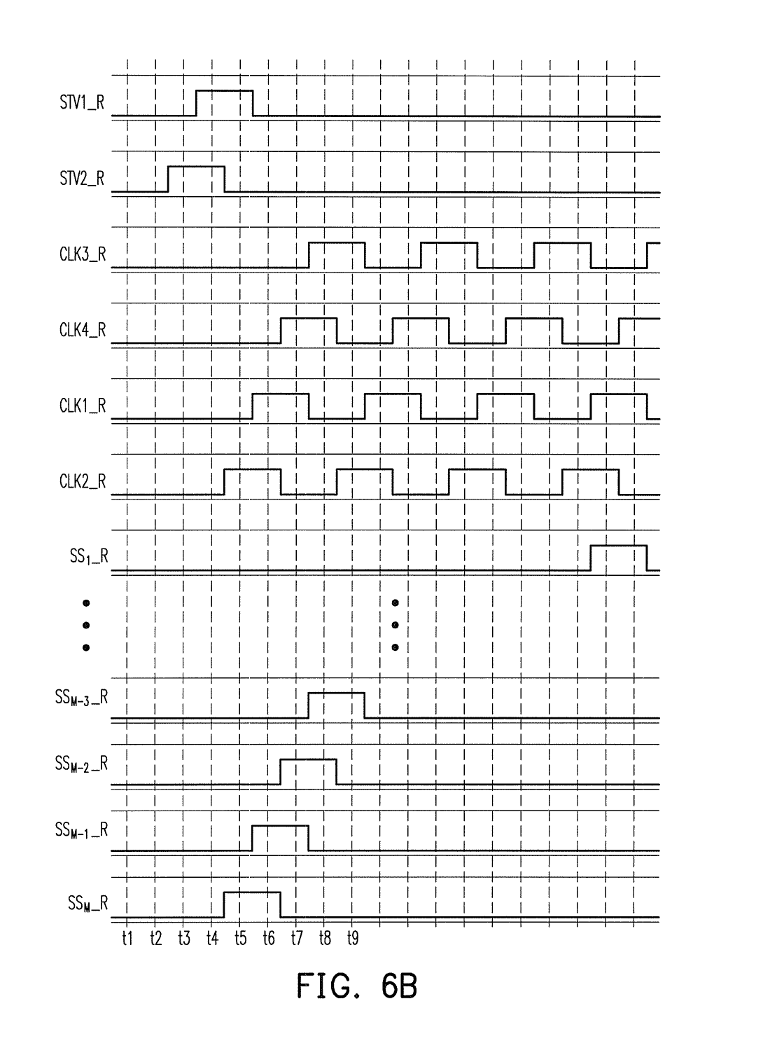

On the other hand, under the backward scan driving state, the start pulse signals STV1_L and STV2_L and clock signals CLK1_L to CLK4_L provided by the timing controller 122 may have signal waveforms as shown in FIG. 6A. The difference between the embodiments of FIG. 6A and FIG. 5 lies in that the timing controller 122 generates the clock signals CLkl_L to CLK4_L in the order of CLK2_L→CLK1_L→CLK4_L→CLK3_L (while it is in the order of CLK3_L→CLK4_L→CLK1_L→CLK2_L under the forward scan driving state), with each being 90 degrees behind a previous clock signal. In addition, in the present embodiment, the enabling time of the first pulse of the clock signal CLK2_L in a frame period is ahead of the enabling time of the start pulse signal STV1_L, and is 50% overlapped with the enabling time of the start pulse signal STV1_L.

More specifically, with respect to the shift registers SR1₁ to SR1_{N} under the backward scan driving state, taking the shift registers SR_{N} to SR_{N-3} as an example, the shift registers SR_{N}, SR_{N-1}, SR_{N-2} and SR_{N-3} sequentially take the clock signals CLK2_L, CLK1_L, CLK4_L and CLK3_L as the first input clock signal RCK1, and sequentially take the clock signals CLK4_L, CLK3_L, CLK2_L and CLK1_L as the second input clock signal RCK2. For an understanding of other operations, reference may be made to the above description with respect to FIG. 2A, FIG. 3A to FIG. 3E, FIG. 4 and FIG. 5A and explanation thereof is therefore not repeated herein.

On the other hand, FIG. 5B and FIG. 6B illustrate sequence of the right side bidirectional shift register apparatus 112_R under forward and backward scan driving states, respectively. Referring to FIG. 2B and FIG. 5B, in the present embodiment, the architecture and operation principle of the right side bidirectional shift register apparatus 112_R and its shift registers SR2₁ to SR2_{M} are the same as those of the left side bidirectional shift register apparatus 112_L. The difference between the bidirectional shift register apparatuses 112_L and 112_R lies in only that the right side bidirectional shift register apparatus 112_R drives the even number row pixels of the display area AA according to the start pulse signals STV1_R and STV2_R and clock signals CLK1_R to CLK4_R.

Specifically, referring to FIG. 5A and FIG. 5B, under the forward scan driving state, the start pulse signals STV1_R and STV2_R correspond to the start pulse signals STV1_L and STV2_L, with the difference therebetween being that the phases of the start pulse signals STV1_R and STV2_R are behind the start pulse signals STV1_L and STV2_L and have a 45 degrees phase difference, respectively. That is, the enabling time of the start pulse signal STV1_L and the enabling time of the start pulse signal STV1_R are 75% overlapped, and the enabling time of the start pulse signal STV2_L and the enabling time of the start pulse signal STV2_R are also 75% overlapped. Similarly, the clock signals CLK1_R to CLK4_R sequentially correspond to the clock signals CLK1_L to CLK4_L, with the difference therebetween being that the phases of the clock signals CLK1_R to CLK4_R are behind the clock signals CLK1_L to CLK4_L and have a 45 degrees phase difference, respectively. That is, the enabling time of the clock signals CLK1_L to CLK4_L and the enabling time of the clock signal CLK1_R to CLK4_R are 75% overlapped, respectively. Based on the difference in the signal sequence, the right side bidirectional shift register apparatus 112_R can sequentially generate the scan signals SS₁_{_{—}}R to SS_{M}_{_{—}}R, which have a certain phase difference with respect to the scan signals SS₁_{_{—}}L to SS_{N}_{_{—}}L, respectively, to drive the even number row pixels, such that each row pixel can be sequentially turned on at a specific interval (for example, a half of the period from time t1 to t2).

In addition, based on the description of the embodiments of FIG. 2A to FIG. 6A and referring to FIG. 6B, people skilled in the art can directly and unambiguously deduce operations of the right side bidirectional shift register apparatus 112_R and its shift registers SR2₁ to SR2_{M} under the backward scan driving state and an explanation thereof is not repeated herein.

In summary, embodiments of the present invention provide a shift register, a bidirectional shift register apparatus and a liquid crystal display panel using the same. The shift register can employ the circuit architecture of the dynamic inverter for node discharge, thereby controlling the voltage level of the outputted scan signals and hence effectively increasing the overall reliability of the bidirectional shift register apparatus. In addition, based on the architecture of the bidirectional shift register apparatus of the embodiment of the present invention, the bidirectional shift register apparatus can use less control signals to achieve forward and backward scan driving scheme, thereby reducing the circuit layout area of the liquid crystal display panel using the bidirectional shift register apparatus.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A shift register, comprising:
a precharge unit, receiving outputs of a previous two-stage of shift register and a next two-stage of shift register both corresponding to the shift register to thereby generate a precharge signal;
a pull up unit, coupled to the precharge unit, receiving the precharge signal and a first input clock signal to thereby output a scan signal; and
a pull down unit, coupled to the precharge unit and the pull up unit, receiving the precharge signal, the first input clock signal and a second input clock signal to control a voltage level of the scan signal.

2. The shift register according to claim 1, wherein the first input clock signal and the second input clock signal are reverse to each other.

3. The shift register according to claim 1, wherein the precharge unit further receives a forward input signal and a backward input signal, such that the precharge unit further generates the precharge signal according to the outputs of the previous two-stage of shift register and the next two-stage of shift register, the forward input signal and the backward input signal.

4. The shift register according to claim 3, wherein the precharge unit comprises:
a first transistor having a gate receiving the output of the previous two-stage of shift register corresponding to the shift register, a first source/drain receiving the forward input signal, and a second source/drain outputting the precharge signal; and
a second transistor having a gate receiving the output of the previous two-stage of shift register corresponding to the shift register, a first source/drain coupled to the second source/drain of the first transistor, and a second source/drain receiving the backward input signal.

5. The shift register according to claim 1, wherein the pull up unit comprises:
a third transistor having a gate receiving the precharge signal, a first source/drain receiving the first input clock signal, and a second source/drain outputting the scan signal; and
a first capacitor having a first terminal coupled to the gate of the third transistor, and a second terminal coupled to the second source/drain of the third transistor.

6. The shift register according to claim 1, wherein the pull down unit comprises:
a first discharge unit receiving the precharge signal and the second input clock signal and thereby determining whether to pull the scan signal down to a reference voltage level; and
a second discharge unit receiving the precharge signal and the first input clock signal and thereby determining whether to maintain the scan signal at the reference voltage level.

7. The shift register according to claim 6, wherein the first discharge unit comprises:
a second capacitor having a first terminal receiving the second input clock signal;
a fourth transistor having a gate coupled to the second source/drain of the first transistor and the first source/drain of the second transistor to receive the precharge signal, a first source/drain coupled to a second terminal of the second capacitor, and a second source/drain coupled to the reference voltage level;
a fifth transistor having a gate coupled to the second terminal of the second capacitor and the first source/drain of the fourth transistor, a first source/drain coupled to the gate of the fourth transistor, and a second source/drain coupled to the reference voltage level; and
a sixth transistor having a gate coupled to the second terminal of the second capacitor and the first source/drain of the fourth transistor, a first source/drain coupled to the second source/drain of the third transistor, and a second source/drain coupled to the reference voltage level.

8. The shift register according to claim 6, wherein the second discharge unit comprises:
a third capacitor having a first terminal receiving the first input clock signal;
a seventh transistor having a gate coupled to the second source/drain of the first transistor and the first source/rain of the second transistor to receive the precharge signal, a first source/drain coupled to a second terminal of the third capacitor, and a second source/drain coupled to the reference voltage level;
an eighth transistor having a gate coupled to the second terminal of the third capacitor and the second source/drain of the seventh transistor, a first source/drain coupled to the gate of the seventh transistor, and a second source/drain coupled to the reference voltage level; and
a ninth transistor having a gate coupled to the second terminal of the third capacitor and the second source/drain of the seventh transistor, a first source/drain coupled to the second source/drain of the third transistor, and a second source/drain coupled to the reference voltage level.

9. A bidirectional shift register apparatus, comprising:
N shift registers as claimed in claim 1 connected in series with each other.

10. The bidirectional shift register apparatus according to claim 9, wherein the precharge unit further receives a forward input signal and a backward input signal, such that the bidirectional shift register apparatus forwardly or backwardly outputs scan signals of the N shift registers according to the forward input signal and the backward input signal.

11. The bidirectional shift register apparatus according to claim 10, wherein:
the first input clock signal and the second input clock signal are reverse to each other,
the precharge unit comprises:
a first transistor having a gate receiving the output of the previous two-stage of shift register corresponding to the shift register, a first source/drain receiving the forward input signal, and a second source/drain outputting the precharge signal; and
a second transistor having a gate receiving the output of the previous two-stage of shift register corresponding to the shift register, a first source/drain coupled to the second source/drain of the first transistor, and a second source/drain receiving the backward input signal,
the pull up unit comprises:
a third transistor having a gate receiving the precharge signal, a first source/drain receiving the first input clock signal, and a second source/drain outputting the scan signal; and
a first capacitor having a first terminal coupled to the gate of the third transistor, and a second terminal coupled to the second source/drain of the third transistor,
the pull down unit comprises:
a first discharge unit receiving the precharge signal and the second input clock signal and thereby determining whether to pull the scan signal down to a reference voltage level; and
a second discharge unit receiving the precharge signal and the first input clock signal and thereby determining whether to maintain the scan signal at the reference voltage level.

12. The bidirectional shift register apparatus according to claim 11, wherein the first discharge unit comprises:
a second capacitor having a first terminal receiving the second input clock signal;
a fourth transistor having a gate coupled to the second source/drain of the first transistor and the first source/drain of the second transistor to receive the precharge signal, a first source/drain coupled to a second terminal of the second capacitor, and a second source/drain coupled to the reference voltage level;
a fifth transistor having a gate coupled to the second terminal of the second capacitor and the first source/drain of the fourth transistor, a first source/drain coupled to the gate of the fourth transistor, and a second source/drain coupled to the reference voltage level; and
a sixth transistor having a gate coupled to the second terminal of the second capacitor and the first source/drain of the fourth transistor, a first source/drain coupled to the second source/drain of the third transistor, and a second source/drain coupled to the reference voltage level.

13. The bidirectional shift register apparatus according to claim 11, wherein the second discharge unit comprises:
a third capacitor having a first terminal receiving the first input clock signal;
a seventh transistor having a gate coupled to the second source/drain of the first transistor and the first source/rain of the second transistor to receive the precharge signal, a first source/drain coupled to a second terminal of the third capacitor, and a second source/drain coupled to the reference voltage level;
an eighth transistor having a gate coupled to the second terminal of the third capacitor and the second source/drain of the seventh transistor, a first source/drain coupled to the gate of the seventh transistor, and a second source/drain coupled to the reference voltage level; and
a ninth transistor having a gate coupled to the second terminal of the third capacitor and the second source/drain of the seventh transistor, a first source/drain coupled to the second source/drain of the third transistor, and a second source/drain coupled to the reference voltage level.

14. A bidirectional shift register apparatus, comprising:
M shift registers as claimed in claim 1 connected in series with each other.

15. The bidirectional shift register apparatus according to claim 14, wherein the precharge unit further receives a forward input signal and a backward input signal, such that the bidirectional shift register apparatus forwardly or backwardly outputs scan signals of the M shift registers according to the forward input signal and the backward input signal.

16. The bidirectional shift register apparatus according to claim 15, wherein:
the first input clock signal and the second input clock signal are reverse to each other,
the precharge unit comprises:
a first transistor having a gate receiving the output of the previous two-stage of shift register corresponding to the shift register, a first source/drain receiving the forward input signal, and a second source/drain outputting the precharge signal; and
a second transistor having a gate receiving the output of the previous two-stage of shift register corresponding to the shift register, a first source/drain coupled to the second source/drain of the first transistor, and a second source/drain receiving the backward input signal,
the pull up unit comprises:
a third transistor having a gate receiving the precharge signal, a first source/drain receiving the first input clock signal, and a second source/drain outputting the scan signal; and
a first capacitor having a first terminal coupled to the gate of the third transistor, and a second terminal coupled to the second source/drain of the third transistor,
the pull down unit comprises:
a first discharge unit receiving the precharge signal and the second input clock signal and thereby determining whether to pull the scan signal down to a reference voltage level; and
a second discharge unit receiving the precharge signal and the first input clock signal and thereby determining whether to maintain the scan signal at the reference voltage level.

17. The bidirectional shift register apparatus according to claim 16, wherein the first discharge unit comprises:
a second capacitor having a first terminal receiving the second input clock signal;
a fourth transistor having a gate coupled to the second source/drain of the first transistor and the first source/drain of the second transistor to receive the precharge signal, a first source/drain coupled to a second terminal of the second capacitor, and a second source/drain coupled to the reference voltage level;
a fifth transistor having a gate coupled to the second terminal of the second capacitor and the first source/drain of the fourth transistor, a first source/drain coupled to the gate of the fourth transistor, and a second source/drain coupled to the reference voltage level; and
a sixth transistor having a gate coupled to the second terminal of the second capacitor and the first source/drain of the fourth transistor, a first source/drain coupled to the second source/drain of the third transistor, and a second source/drain coupled to the reference voltage level.

18. The bidirectional shift register apparatus according to claim 16, wherein the second discharge unit comprises:
a third capacitor having a first terminal receiving the first input clock signal;
a seventh transistor having a gate coupled to the second source/drain of the first transistor and the first source/rain of the second transistor to receive the precharge signal, a first source/drain coupled to a second terminal of the third capacitor, and a second source/drain coupled to the reference voltage level;
an eighth transistor having a gate coupled to the second terminal of the third capacitor and the second source/drain of the seventh transistor, a first source/drain coupled to the gate of the seventh transistor, and a second source/drain coupled to the reference voltage level; and
a ninth transistor having a gate coupled to the second terminal of the third capacitor and the second source/drain of the seventh transistor, a first source/drain coupled to the second source/drain of the third transistor, and a second source/drain coupled to the reference voltage level.

19. A liquid crystal display panel, comprising:
a display area;
a first bidirectional shift register apparatus, disposed on a left side of the display area, and comprising N shift registers as claimed in claim 1 connected in series with each other; and
a second bidirectional shift register apparatus, disposed on a right side of the display area, and comprising M shift registers as claimed in claim 1 connected in series with each other.

20. A liquid crystal display, comprising:
a liquid crystal display panel, comprising:
a display area;
a first bidirectional shift register apparatus, disposed on a left side of the display area, and comprising N shift registers as claimed in claim 1 connected in series with each other; and
a second bidirectional shift register apparatus, disposed on a right side of the display area, and comprising M shift registers as claimed in claim 1 connected in series with each other;
a driving circuit coupled to and configured to drive the liquid crystal display panel; and
a backlight module providing a backlight source for the liquid crystal display panel.
